(19) United States
(12) Patent Application Publication
(10) Pub. No.: US 2024/0120219 A1
(43) Pub. Date: Apr. 11, 2024

(54) BONDING APPARATUS AND BONDING METHOD

(71) Applicant: SHINKAWA LTD., Tokyo (JP)

(72) Inventor: Yuichiro NOGUCHI, Tokyo (JP)

(73) Assignee: SHINKAWA LTD., Tokyo (JP)

(21) Appl. No.: 18/275,806

(22) PCT Filed: Feb. 5, 2021
(86) PCT No.: PCT/JP2021/004389

§ 371 Date: Aug. 3, 2023

(51) Int. Cl. H01L 21/67; H01L 21/687

(52) U.S. Cl. CPC H01L 21/67144; H01L 21/67259; H01L 21/67294; H01L 21/68714

(57) ABSTRACT

A bonding apparatus includes: a movable bonding head part that holds a top camera and a bonding tool disposed at an offset distance from the top camera; a bottom camera capable of photographing the bonding head part; a reference member having a reference mark and fixed to a position that is at a predetermined distance from the bottom camera; and a calculation part that calculates a change amount in the offset distance based on the predetermined distance, a position of the reference mark detected by the top camera, and a position of a chip detected by the bottom camera, when the bonding head part moves such that the reference mark is positioned in the field of view of the top camera and the chip held by the bonding tool is positioned in the field of view of the bottom camera.

### TECHNICAL FIELD

The present invention relates to a bonding apparatus and a bonding method.

### RELATED ART

Conventionally, a mounting method for bonding a chip to a substrate has been disclosed to include: a first chip position calculation process of acquiring an image of an upper surface of a reference chip and an image of a lower surface of a correction chip by a two-field-of-view camera with upper and lower fields of view (FoV) to calculate each position of each chip; a second chip movement process of placing the correction chip on a suction stage after moving the reference chip to a position at which a separation distance between the chips becomes a predetermined offset amount based on a deviation amount between the chips calculated from each position of each chip; a second chip position calculation process of acquiring an image of an upper surface of the correction chip to calculate a second position of the correction chip; and a correction amount calculation process of calculating a correction amount for the predetermined offset amount based on the position of the reference chip and the second position of the correction chip (see Patent Document 1). This mounting method suppresses over-time position deviation of the mounting position of the chip by calculating a change amount (correction amount) for the predetermined offset distance.

### RELATED ART DOCUMENT

### Patent Document

Patent Document 1: International Publication No. 2015/119274

### SUMMARY OF INVENTION

### Problems to be Solved by Invention

However, in the method disclosed in Patent Document 1, since it is required to perform a plurality of processes to calculate the change amount in the offset distance, the process for calculating the change amount in the offset distance takes time.

The present invention has been made in view of such circumstances, and it is an objective of the present invention to provide a bonding apparatus and a bonding method capable of shortening a process time for calculating a change amount in an offset distance.

### Means for Solving Problems

A bonding apparatus according to an aspect of the present invention includes a bonding head part, a second camera, a reference member, and a calculation part. The bonding head part is movable and holds a first camera installed with an optical system oriented toward one side and a bonding tool arranged apart from the first camera by an offset distance. The second camera is installed with an optical system oriented toward another side to be capable of photographing the bonding head part. The reference member has a reference mark on a surface on the another side and is fixed at a position spaced apart from the second camera by a predetermined distance. The calculation part calculates a change amount in the offset distance based on the predetermined distance, a position of the reference mark detected by the first camera, and a position of a chip detected by the second camera, when the bonding head part moves such that the reference mark is positioned within a field of view of the first camera and the chip held by the bonding tool is positioned within a field of view of the second camera.

According to the above configuration, the change amount in the offset distance is calculated based on the predetermined distance, the position of the reference mark detected by the first camera, and the position of the chip detected by the second camera, when the bonding head part moves such that the reference mark is positioned within the field of view of the first camera and the chip held by the bonding tool is positioned within the field of view of the second camera. Accordingly, while simultaneously detecting the position of the reference mark and the position of the chip held by the bonding tool, the change amount in the offset distance can be calculated. Thus, compared to the conventional bonding apparatus which detects the reference mark and detects the chip sequentially in different processes, the process time for calculating the change amount in the offset distance can be shortened.

In the bonding apparatus, the calculation part may detect the position of the reference mark based on a first image captured by the first camera, and detect the position of the chip based on a second image captured by the second camera.

In the bonding apparatus, the calculation part may measure a deviation amount of the reference mark with respect to the first camera based on the first image, and measure a deviation amount of the chip with respect to the second camera based on the second image.

The bonding apparatus may further include a movement control part which controls movement of the bonding head part and determines a movement amount of the bonding head part based on the calculated change amount in the offset distance.

In the bonding apparatus, the second camera and the reference member may be integrated.

In the bonding apparatus, the predetermined distance may be set based on the offset distance.

A bonding method according to another aspect of the present invention is a bonding method of a bonding apparatus including a bonding head part, a second camera, and a reference member. The bonding head part is movable and holds a first camera installed with an optical system oriented toward one side and a bonding tool arranged apart from the first camera by an offset distance. The second camera is installed with an optical system oriented toward another side to be capable of photographing the bonding head part. The reference member has a reference mark on a surface on the another side and is fixed at a position spaced apart from the second camera by a predetermined distance. The bonding method includes steps below. A position of the reference mark is detected by the first camera, and a position of a chip held by the bonding tool is detected by the second camera. A change amount in the offset distance is calculated based on the predetermined distance, the detected position of the reference mark, and the detected position of the chip.

According to the above configuration, the change amount in the offset distance is calculated based on the predetermined distance, the position of the reference mark detected by the first camera, and the position of the chip detected by the second camera, when the bonding head part moves such that the reference mark is positioned within the field of view of the first camera and the chip held by the bonding tool is positioned within the field of view of the second camera. Accordingly, while simultaneously detecting the position of the reference mark and the position of the chip held by the bonding tool, the change amount in the offset distance can be calculated. Thus, compared to the conventional bonding apparatus which detects the reference mark and detects the chip sequentially in different processes, the process time for calculating the change amount in the offset distance can be shortened.

### Effect of Invention

According to the present invention, it is possible to shorten a process time for calculating a change amount in an offset distance.

### BRIEF DESCRIPTION OF DRAWINGS

FIG. 1 is a side view showing a schematic configuration of a bonding apparatus according to an embodiment.

FIG. 2 is a side view showing a positional relationship between a bonding tool and a top camera shown in FIG. 1.

FIG. 3 is a side view showing an example of a positional relationship between a bottom camera and a reference member shown in FIG. 1.

FIG. 4 is a side view showing another example of the positional relationship between the bottom camera 28 and the reference member shown in FIG. 1.

FIG. 5 is a schematic view showing arrangements of a bonding head part, a bottom camera, and a reference member of the bonding apparatus according to an embodiment.

FIG. 6 is a schematic view showing a first image captured by the top camera shown in FIG. 5.

FIG. 7 is a schematic view showing a second image captured by the bottom camera shown in FIG. 5.

FIG. 8 is a flowchart illustrating a bonding method in an embodiment.

### DESCRIPTION OF EMBODIMENTS

An embodiment of the present invention will be described below. In the following description of the drawings, the same or similar parts will be denoted by the same or similar reference signs. However, the drawings are schematic. Thus, specific dimensions and the like should be determined with reference to the following description. In addition, obviously, portions with different dimensional relationships and ratios are also included among the drawings. Furthermore, the technical scope of the present invention should not be construed as being limited to this embodiment.

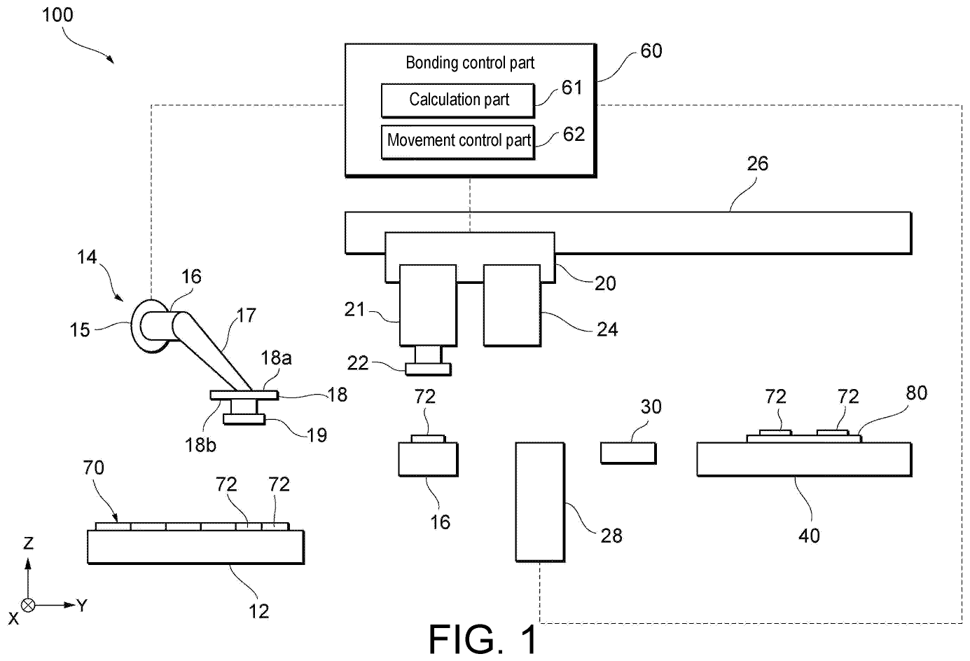

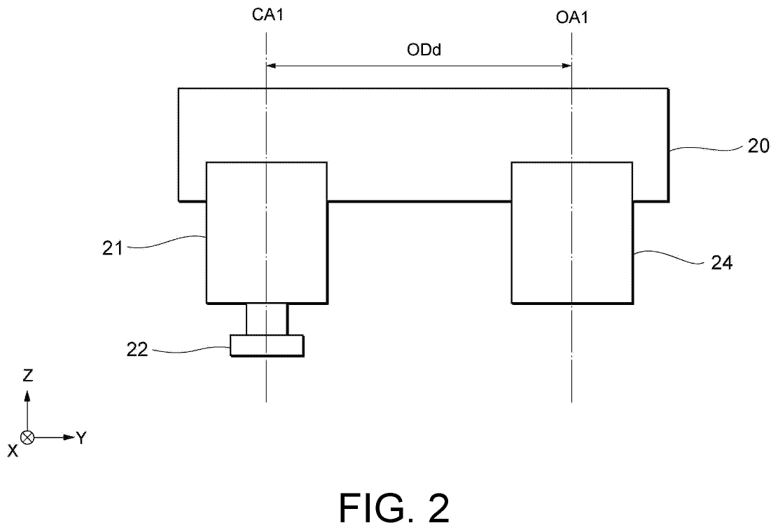

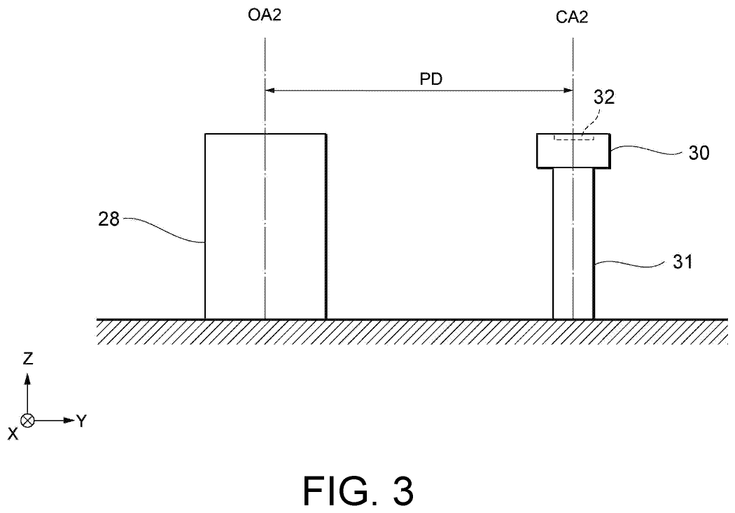

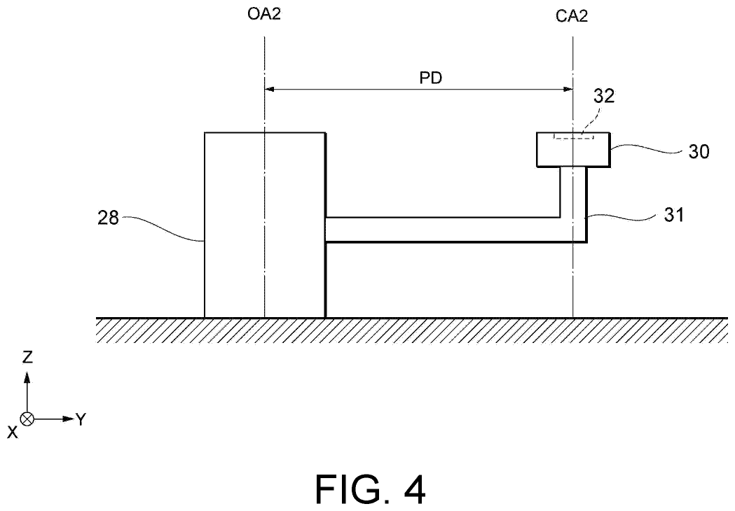

First, a configuration of a bonding apparatus according to an embodiment will be described with reference to FIG. 1 to FIG. 4. FIG. 1 is a side view showing a schematic configuration of a bonding apparatus 100 according to an embodiment. FIG. 2 is a side view showing a positional relationship between a bonding tool 22 and a top camera 24 shown in FIG. 1. FIG. 3 is a side view showing an example of a positional relationship between a bottom camera 28 and a reference member 30 shown in FIG. 1. FIG. 4 is a side view showing another example of the positional relationship between the bottom camera 28 and the reference member 30 shown in FIG. 1.

As shown in FIG. 1, the bonding apparatus 100 includes a wafer holding part 12, a handling unit 14, a bonding head part 20, an XY table 26, a bottom camera 28, a reference member 30, a bonding stage part 40, and a bonding control part 60. In the following description, a direction parallel to a bonding target surface will be taken as an XY-axis direction, and a direction perpendicular to the bonding target surface will be taken as a Z-axis direction.

The bonding apparatus 100 is a semiconductor manufacturing apparatus for bonding a chip 72 (also referred to as “die”) of a wafer 70 to a substrate 80. The chip 72 has a front surface on which an integrated circuit pattern is formed and a back surface opposite to the front surface. The bonding apparatus 100 described below aligns the chip 72 with a mounting part of the substrate 80 and bonds the chip 72 to the substrate 80 such that the back surface of the chip 72 faces the substrate 80. Such a bonding apparatus 100 is called a die bonding apparatus.

The wafer holding part 12 is configured to hold the wafer 70 transported by a wafer transport tool (not shown) or the like. The wafer 70 is diced into a grid pattern and includes a plurality of chips 72 cut into small pieces. The wafer holding part 12 holds the plurality of chips 72 by, for example, vacuum-sucking the wafer 70 or attaching the wafer 70 to a film.

Each chip 72 of the wafer 70 held by the wafer holding part 12 is bonded to the substrate 80. For example, the chip 72 is picked up from the wafer 70 by the handling unit 14, and the back surface side of the chip 72, which is to be connected to the substrate, is turned to face upward by an inversion operation of the handling unit 14. The inverted chip 72 is delivered to the bonding tool 22.

More specifically, the handling unit 14 includes a stepping motor 15, a rotating shaft 16, an arm 17, a base 18, and a pickup tool 19. The stepping motor 15 is an inversion drive mechanism that rotates the rotating shaft 32 to invert the base 18 and the pickup tool 19. The arm 17 has one end attached to the rotating shaft 16, extends obliquely downward in the Z-axis direction from the rotating shaft 16, and has another end attached to an upper surface 18a of the base 18 in the Z-axis direction. The base 18 is a plate-shaped member fixed to a tip of the arm 17 by a bolt or the like. The pickup tool 19 is attached to a lower surface 18b of the base 18 in the Z-axis direction. The pickup tool 19 is movable in the Z-axis direction by a Z-axis drive mechanism (not shown).

The handling unit 14 shown in FIG. 1 shows a case where the pickup tool 19 faces downward, that is, a state in which the upper surface 18a of the base 18 faces upward in the Z-axis direction. In this state, by moving the handling unit 14 to above the wafer holding part 12, pushing up the chip 72 through the film from below the wafer holding part 12, and sucking the chip 72 on the film from above by the pickup tool 14, the chip 72 is picked up by the pickup tool 14 of the handling unit 14. On the other hand, when the rotating shaft 32 is rotated by the stepping motor 15 and the base 18 and the pickup tool 19 are inverted, the lower surface 18b of the base 18 faces upward in the Z direction, and the pickup tool 19 also faces upward. Accordingly, the handling unit 14 can invert the picked up chip 72.

The bonding head part 20 is configured to suck the inverted chip 72 picked up from the wafer holding part 12 and transport the chip 72 to a bonding position of the substrate 80 to bond the chip 72 to the substrate 80.

The bonding head part 20 holds the bonding tool 22 and the top camera 24. Specifically, the bonding tool 22 is attached to the bonding head part 20 via a Z-axis drive mechanism 21, and the top camera 24 is attached to the bonding head part 20 at a position separated from the bonding tool 22. The bonding head part 20 is movable in the X-axis direction and the Y-axis direction by the XY table 26, and accordingly the bonding tool 22 and the top camera 24 move in at least one of the X-axis direction and the Y-axis direction.

The bonding apparatus 100 is not limited to the case of including one bonding head part 20. For example, the bonding apparatus 100 may include a plurality of bonding head parts 20. In that case, by providing a plurality of bonding head parts, bonding can be performed on a plurality of substrates at the same time.

The bonding tool 22 is, for example, a collet that holds the chip 72 by suction. Such a collet is formed in a rectangular parallelepiped shape or a truncated cone shape and is configured to contact and hold the outer edge of the chip 72 from the front surface side of the chip 72 on which the integrated circuit pattern is formed. The collet, which serves as the bonding tool 22, has a central axis parallel to the Z-axis direction, and is movable in the Z-axis direction, the X-axis direction, and the Y-axis direction respectively by the Z-axis drive mechanism 21 and the XY table 26.

The bonding tool 22 is attached to the bonding head part 20 via a θ-axis drive mechanism and a tilt drive mechanism (not shown), and rotates about the Z-axis and is movable in a tilt direction (inclination direction) by these drive mechanisms.

The top camera 24 is configured to acquire image information of the reference member 30 fixed to the bottom camera 28. For example, the top camera 24 is a digital camera including an optical system such as a lens and an imaging device such as a charge coupled device (CCD) image sensor, a complementary metal oxide semiconductor (CMOS) image sensor, etc. The top camera 24 is arranged with its optical system oriented toward one side, i.e., the Z-axis negative direction side in FIG. 1, and has an optical axis extending vertically downward.

As shown in FIG. 2, the bonding tool 22 is arranged at the bonding head part 20 at an offset distance ODd from the top camera 24. More specifically, the bonding tool 22 and the top camera 24 are arranged such that a central axis CA1 of the bonding tool 22 in the Y-axis direction and an optical axis OA1 of the top camera 24 are at positions separated by the offset distance ODd.

In such a bonding apparatus, the distance between the bonding tool and the top camera may change due to temperature changes, aging, etc. Then, when the offset distance changes from the offset distance ODd, which is a prescribed basis distance, an error corresponding to the change amount is generated, which results in, for example, a decrease in the accuracy of the bonding position to the substrate.

Thus, some bonding apparatuses adopt a method such as adding a process for obtaining a change amount in the offset distance before the bonding process. However, such a method involves addition of a new process, so there is a risk of taking a long time for obtaining the change amount in the offset distance.

Returning to FIG. 1, the bottom camera 28 is configured to acquire image information of the bonding tool 22. Similar to the top camera 24, the bottom camera 28 is a digital camera including, for example, an optical system and an imaging element. The bottom camera 28 is arranged with its optical system oriented toward another side, i.e., the Z-axis positive direction side in FIG. 1, and has an optical axis extending vertically upward. In other words, the bottom camera 28 is arranged to face the bonding tool 22 and the top camera 24 to be capable of photographing a bottom surface (tip surface) of the bonding tool 22. Further, the bottom camera 28 is installed at a position around the bonding stage part 40 at which the bottom surface of the bonding tool 22 can be photographed.

The reference member 30 is a member that serves as a basis when calculating the change amount in the offset distance ODd between the bonding tool 22 and the top camera 24. Calculation of the change amount in the offset distance ODd will be described later.

As shown in FIG. 3, the bottom camera 28 is provided and fixed on a fixed member or a basis member. The reference member 30 is fixed at a position spaced apart from the bottom camera 28 by a predetermined distance PD. More specifically, a support member 31 provided on the fixed member or the basis member is fixed at a position separated from the bottom camera 28 in the Y-axis direction. The reference member 30 is supported by the support member 31. As a result, the bottom camera 28 and the reference member 30 are arranged such that an optical axis OA2 of the bottom camera 28 and a central axis CA2 of the reference member 30 in the Y-axis direction are at positions separated by the predetermined distance PD.

As described above, since the bottom camera 28 and the reference member 30 are fixed, different from the offset distance described above, the predetermined distance PD between the bottom camera 28 and the reference member 30 is not affected by temperature changes, aging, etc., or the influence thereon is so small that it can be ignored. Thus, the predetermined distance PD may be regarded as not changing (invariant).

The reference member 30 has a reference mark 32 on the surface on the bonding head part 20 side (upper surface in FIG. 3). The reference member 30 is arranged at a height such that its upper surface is within the range of the depth of field of the top camera 24.

The shape of the reference mark 32 is not particularly limited as long as its position and orientation within the field of view (FoV) of the top camera 24 can be recognized. Thus, the reference mark 32 may be, for example, a rectangular mark composed of a rectangular block, or may be a cross-shaped mark composed of a cross-shaped groove (hole) formed in a rectangular block.

Although FIG. 3 shows an example in which the bottom camera 28 and the reference member 30 are separate members, the present invention is not limited thereto. As shown in FIG. 4, for example, the support member 31 may be a member that extends from the bottom camera 28 along the Y-axis direction and connects the bottom camera 28 with the reference member 30. In this case, the bottom camera 28 and the reference member 30 are integrally configured as one member. Accordingly, the reference member 30 can be easily fixed at a position separated from the bottom camera 28 by the predetermined distance PD.

The predetermined distance PD between the bottom camera 28 and the reference member 30 is preferably set based on the offset distance ODd described above. For example, the predetermined distance PD may be equal to the offset distance ODd (PD=ODd), may be obtained by adding a predetermined length (ΔL) to the offset distance ODd (PD=ODd+ΔL), or may be obtained by subtracting a predetermined length (ΔL) from the offset distance ODd (PD=ODd-ΔL).

Thus, by setting the predetermined distance PD between the bottom camera 28 and the reference member 30 based on the offset distance ODd described above (e.g., setting the predetermined distance PD to a value equal to the offset distance ODd), it is possible to simply and easily calculate the change amount in the offset distance, which will be described later.

Returning to FIG. 1, the bonding stage part 40 is a stage for bonding the chip 72 to the mounting part of the substrate 80. The bonding stage part 40 is provided with a movement mechanism (not shown) for moving the substrate 80 in at least one of the X-axis direction and the Y-axis direction, a heater (not shown) for heating the substrate 80, etc. These components are controlled by the bonding control part 60.

The bonding control part 60 is configured to control the entire bonding apparatus 100. More specifically, the bonding control part 60 is configured to control processes necessary for bonding performed by the bonding apparatus 100. Specifically, the bonding control part 60 controls processes including a bonding process performed by the bonding head part 20, an exchange process of the wafer 70 held by the wafer holding part 12, a transport process of the chip 72 and the substrate 80, etc. The bonding control part 60 is connected to be capable of transmitting and receiving signals among the components of the bonding apparatus 100 within a range necessary for these processes, and controls the operation of each of the components.

For example, the bonding control part 60 is a computer device including a microprocessor (not shown) such as a central processing unit (CPU), a memory (not shown) such as a read only memory (ROM) and a random access memory (RAM), etc. The memory stores in advance a bonding program for performing processes necessary for bonding and other necessary information. The bonding control part 60 includes, for example, a program for causing a computer to execute each process, and is configured to be capable of executing each process related to a bonding method to be described later.

Further, the bonding control part 60 includes a calculation part 61 and a movement control part 62 as functional blocks.

The calculation part 61 is configured to calculate the change amount in the offset distance when the bonding head part moves such that the reference mark 32 is positioned within the field of view of the top camera 24 and the chip 72 held by the bonding tool 22 is positioned within the field of view of the bottom camera 28. The calculation part 61 is configured to calculate the change amount in the offset distance based on the predetermined distance PD, the position of the reference mark 32 detected by the top camera 24, and the position of the chip 72 detected by the bottom camera 28 (details will be described later). Accordingly, while simultaneously detecting the position of the reference mark 32 and the position of the chip 72 held by the bonding tool 22, the change amount in the offset distance can be calculated. Thus, compared to the conventional bonding apparatus which detects the reference mark 32 and detects the chip 72 sequentially in different processes, the process time for calculating the change amount in the offset distance can be shortened.

The movement control part 62 is configured to control movement of the bonding head part 20. More specifically, the movement control part 62 is configured to determine a movement amount of the bonding head part 20 based on the calculated change amount in the offset distance. Accordingly, the bonding head part 20 can be moved by a movement amount corrected in consideration of the calculated change amount in the offset distance. Thus, the accuracy of the bonding position of the chip 72 held by the bonding tool 22 can be improved.

FIG. 1 shows part of functional blocks necessary for bonding in this embodiment. Thus, the bonding control part 60 may also include functional blocks in addition to those shown in FIG. 1.

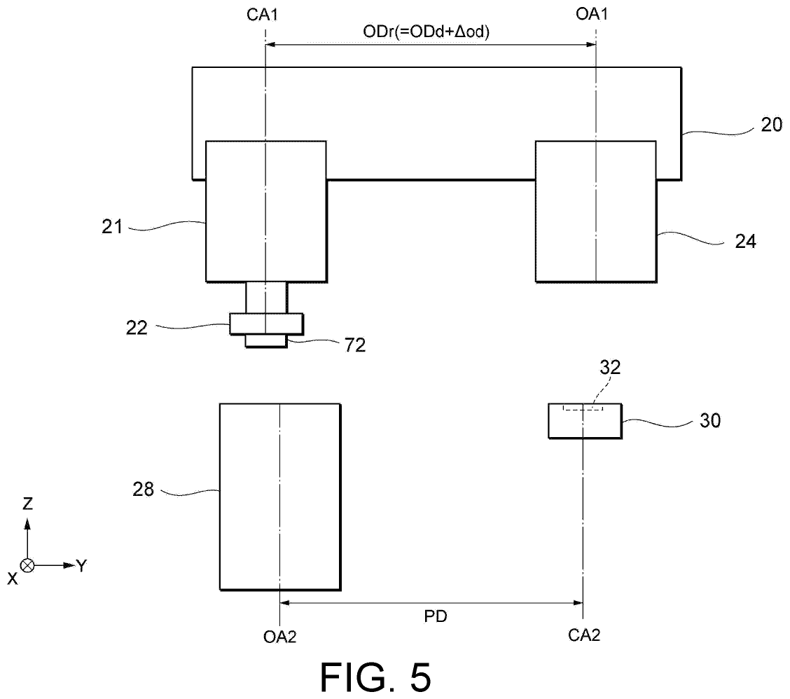

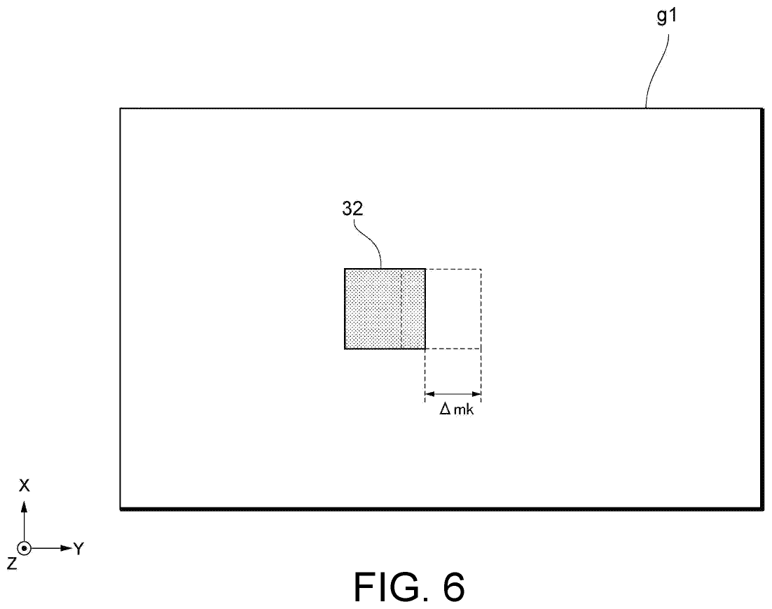

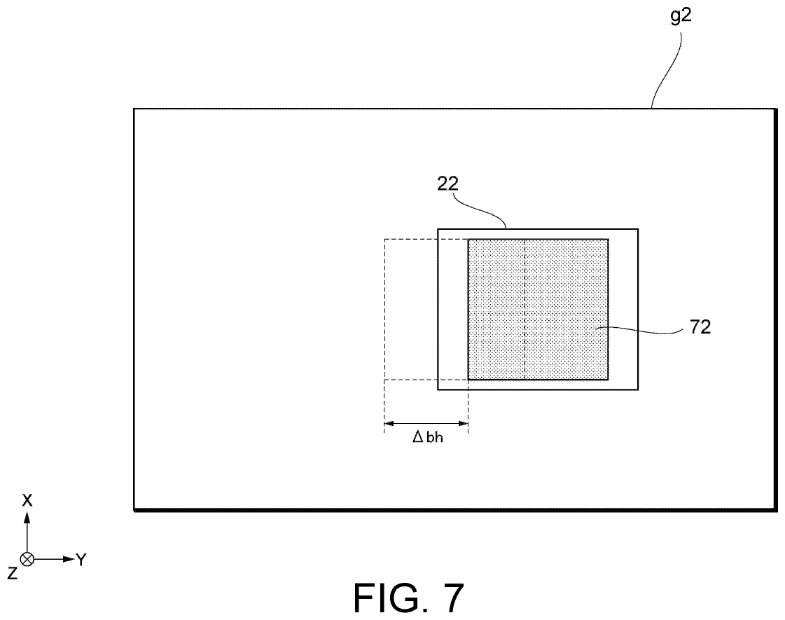

Next, calculation of the change amount in the offset distance of the bonding apparatus according to an embodiment will be described with reference to FIG. 5 to FIG. 7. FIG. 5 is a schematic view showing arrangements of the bonding head part 20, the bottom camera 28, and the reference member 30 of the bonding apparatus 100 according to an embodiment. FIG. 6 is a schematic view showing a first image g1 captured by the top camera 24 shown in FIG. 5. FIG. 7 is a schematic view showing a second image g2 captured by the bottom camera 28 shown in FIG. 5.

As shown in FIG. 5, with the bonding tool 22 holding the chip 72, the movement control part 62 causes the bonding head part 20 to move to a position at which the reference mark 32 is positioned within the field of view of the top camera 24 and the chip 72 held by the bonding tool 22 is positioned within the field of view of the bottom camera 28. Specifically, in the case where the predetermined distance PD is equal to the offset distance ODd (PD=ODd), the movement control part 62 causes the bonding head part 20 to move such that the top camera 24 is directly above the reference member 30 (i.e., the optical axis OA1 of the top camera 24 is aligned with the central axis CA2 of the reference member 30 in the Y-axis direction), and the bonding tool 22 is directly above the bottom camera 28 (i.e., the optical axis OA2 of the bottom camera 28 is aligned with the central axis CA1 of the bonding tool 22 in the Y-axis direction).

Since the offset distance ODd is originally equal to the predetermined distance PD (OD=PD), if the offset distance is invariant (fixed), then after movement of the bonding head part 20, the optical axis OA1 of the top camera 24 should be aligned with the central axis CA2 of the reference member 30 in the Y-axis direction, and the optical axis OA2 of the bottom camera 28 should be aligned with the central axis CA1 of the bonding tool 22 in the Y-axis direction. However, as mentioned above, the offset distance changes due to heat, aging, etc., and an actual offset distance ODr includes the offset distance ODd, which is a prescribed basis distance, and a change amount Δod (ODr=ODd+Δod).

In this state, that is, at the positions shown in FIG. 5, in the state in which the optical axis OA1 of the top camera 24 is not aligned with the central axis CA2 of the reference member 30 in the Y-axis direction and a deviation occurs, and the optical axis OA2 of the bottom camera 28 is not aligned with the central axis CA1 of the bonding tool 22 in the Y-axis direction and a deviation occurs, the bonding control part 60 drives the top camera 24 to photograph the reference member 30 within the field of view to acquire a first image g1, and drives the bottom camera 28 to photograph the chip 72 held by the bonding tool 22 within the field of view to acquire a second image g2.

Herein, consider a case where a deviation amount Δmk along the Y-axis direction, for example, occurs between the optical axis OA1 of the top camera 24 and the central axis CA2 of the reference member 30. In this case, the calculation part 61 detects the position of the reference mark 32 based on the first image g1 shown in FIG. 6. In the case where the deviation amount Δmk does not occur (Δmk=0), the reference mark 32 of the reference member 30 should be at the original position indicated by a dashed line in FIG. 6 in the first image. Thus, the bonding control part 60 captures a first image in a state in which the deviation amount Δmk does not occur, and detects the position of the reference mark 32 and stores the position of the reference mark 32 in the first image in advance. Then, by analyzing the first image g1 based on the stored position of the reference mark 32, the calculation part 61 can measure the deviation amount Δmk of the reference mark 32 with respect to the top camera 24.

Similarly, consider a case where a deviation amount Δbh along the Y-axis direction, for example, occurs between the optical axis OA2 of the bottom camera 28 and the central axis CA1 of the bonding tool 22. In this case, the calculation part 61 detects the position of the chip 72 held by the bonding tool 22 based on the second image g2 shown in FIG. 7. In the case where the deviation amount Δbh does not occur (Δbh=0), the chip 72 held by the bonding tool 22 should be at the original position indicated by a dashed line in FIG. 7 in the second image. Thus, the bonding control part 60 captures a second image in a state in which the deviation amount Δbh does not occur, and detects the position of the chip 72 held by the bonding tool 22 and stores the position of the chip 72 in the second image in advance. Then, by analyzing the second image g2 based on the stored position of the chip 72, the calculation part 61 can measure the deviation amount Δbh of the chip 72 with respect to the bottom camera 28.

Then, the calculation part 61 calculates the change amount Δod in the offset distance based on the predetermined distance PD, the deviation amount Δmk of the reference member 30 with respect to the top camera 24 measured based on the first image g1, and the deviation amount Δbh of the chip 72 with respect to the bottom camera 28 measured based on the second image g2.

Specifically, the calculation part 61 obtains the change amount Δod in the offset distance using Formula (1) below.

Δod=PD−Δbh+Δmk (1)

In this manner, by detecting the position of the reference mark 32 based on the first image g1 captured by the top camera 24 and detecting the position of the chip 72 held by the bonding tool 22 based on the second image g2 captured by the bottom camera 28, the positions of the reference mark 32 and the chip 72 can be easily detected.

Further, by measuring the deviation amount Δmk of the reference mark 32 based on the first image g1 and measuring the deviation amount Δbh of the chip 72 based on the second image g2, the change amount Δod in the offset distance can be easily calculated based on the measured deviation amount Δmk and deviation amount Δbh.

The movement control part 62 determines the movement amount of the bonding head part 20 based on the calculated change amount Δod in the offset distance. More specifically, the movement control part 62 determines the actual movement amount of the bonding head part 20 such that the movement distance including the change amount Δod in the offset distance is equal to the original movement amount of the bonding head part 20. For example, in the case where the change amount Δod in the offset distance is a positive value, the movement control part 62 determines the movement amount of the bonding head part 20 to be a value obtained by subtracting the change amount Δod from the original movement amount. On the other hand, in the case where the change amount Δod in the offset distance is a negative value, the movement control part 62 determines the movement amount of the bonding head part 20 to be a value obtained by adding the change amount Δod to the original movement amount.

FIG. 6 and FIG. 7 show examples in which the deviation amount Δmk of the reference mark 32 and the deviation amount Δbh of the chip 72 occur along the Y-axis direction, but the present invention is not limited thereto. For example, in addition to the Y-axis direction, the calculation part 61 may measure a deviation amount of the reference mark 32 and a deviation amount of the chip 72 along the X-axis direction, and calculate a change amount in the offset distance along the X-axis direction. Similarly, regarding the tilt (inclination) with respect to the Z-axis, the calculation part 61 may measure a deviation amount (deviation angle) of the reference mark 32 and a deviation amount (deviation angle) of the chip 72, and regarding the offset distance, the calculation part 61 may calculate a change amount (change angle) in the tilt with respect to the Z-axis.

Moreover, the first image g1 and the second image g2 are not limited to the case of being captured by temporarily stopping the bonding head part 20 at the position shown in FIG. 5. For example, while the movement control part 62 causes the bonding head part 20 to move, when the bonding head part 20 reaches the position shown in FIG. 5, the bonding control part 60 may acquire the first image g1 and the second image g2.

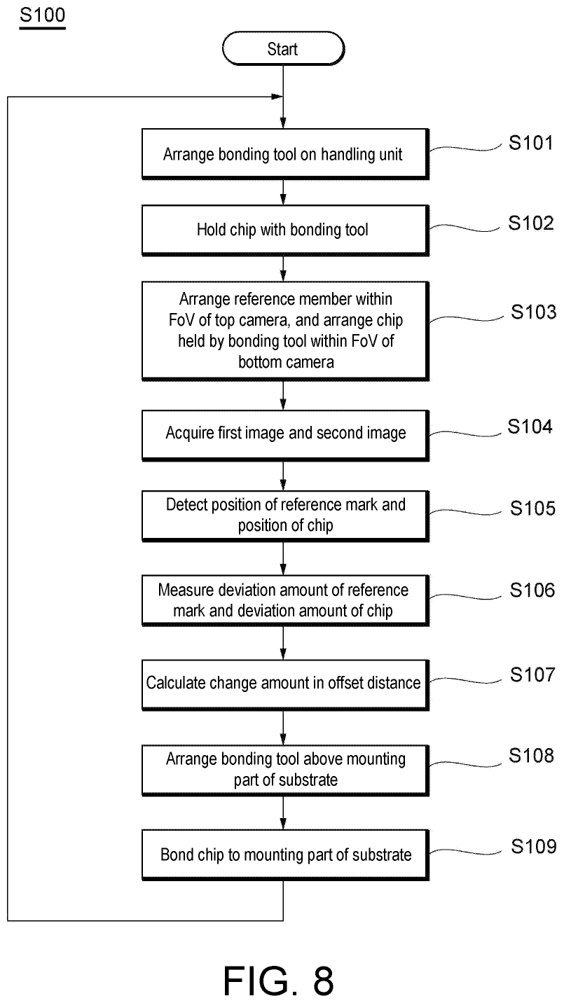

Next, a bonding method according to an embodiment will be described with reference to FIG. 8. FIG. 8 is a flowchart illustrating a bonding method in an embodiment. The bonding method in this embodiment may be performed using the bonding apparatus 100 described above.

When bonding the chip 72 onto the substrate 80, the bonding control part 60 performs a bonding process S100 shown in FIG. 8. That is, first, the movement control part 62 causes the bonding head part 20 to move and arranges the bonding tool 22 at a position directly above the handling unit 14 which has inverted the picked up chip 72 (S101). At this position, the bonding control part 60 drives the Z-axis drive mechanism 21 to lower the bonding tool 22 and holds the chip 72 by suction at the tip of the bonding tool 22 (S102). After holding the chip 72 by suction in step S102, the bonding control part 60 drives the Z-axis drive mechanism 21 to raise the bonding tool 22 to a specified height.

Next, the movement control part 62 causes the bonding head part 20 to move to position the reference member 30 within the field of view of the top camera 24 and position the chip 72 held by the bonding tool 22 within the field of view of the bottom camera 28 (S103). Then, at this position, the bonding control part 60 photographs the reference mark 32 of the reference member 30 within the field of view using the top camera 24 to acquire a first image g1, and photographs the chip 72 held by the bonding tool 22 within the field of view using the bottom camera 28 to acquire a second image g2 (S104). The first image g1 and the second image g2 acquired in step S104 are stored to a memory or the like.

Before acquiring the second image g2 in step S104, the bonding control part 60 may drive the Z-axis drive mechanism 21 to lower the bonding tool 22 holding the chip 72 within the range of the depth of field of the bottom camera 28. In this case, since the image is captured in the state in which the bonding tool 22 holding the chip 72 is lowered, in the measurement of the deviation amount to be described later, a deviation amount of the chip 72 occurring along with the movement in the Z-axis direction by the Z-axis drive mechanism 21 may be included.

Further, the bonding control part 60 may perform quality determination on the chip 72 based on the second image g2. As a result of image analysis of the second image g2, in the case where it can be determined that the chip 72 has a defect such as a crack, the bonding control part 60 stops bonding of this chip 72.

Next, the calculation part 61 detects the position of the reference mark 32 at the reference member 30 based on the first image g1 acquired in step S104, and detects the position of the chip 72 held by the bonding tool 22 based on the second image g2 acquired in step S105 (S105).

Next, the calculation part 61 measures a deviation amount Δmk of the reference mark 32 with respect to the top camera 24 based on the position of the reference mark 32 detected in step S106, and measures a deviation amount Δbh of the chip 72 with respect to the bottom camera 28 based on the position of the chip 72 detected in step S107 (S106). The deviation amount Δmk of the reference mark 32 and the deviation amount Δbh of the chip 72 measured in step S106 are stored to a memory or the like.

Next, the calculation part 61 calculates a change amount Δod in the offset distance using Formula (1) described above based on the predetermined distance PD, the deviation amount Δmk of the reference mark, and the deviation amount Δbh of the chip 72 (S107).

Next, the movement control part 62 causes the bonding head part 20 to move and arranges the bonding tool 22 at a position directly above the mounting part of the substrate 80 (S108). At this time, considering the change amount Δod in the offset distance calculated in step S107, the movement control part 62 determines the movement amount of the bonding head part 20 such that the bonding tool 22 is directly above the mounting part of the substrate 80.

Then, the bonding control part 60 lowers the bonding tool 22 to the vicinity of the substrate 80 and bonds the chip 72 to the mounting part of the substrate 80 (S109). Upon completion of bonding of one chip 72, the process returns to step S101 to perform bonding of a next chip 72.

When the process from step S101 to step S109 for bonding one chip 72 is taken as one cycle, in a conventional bonding apparatus, with 383 chips taken as a sample, the time per cycle (hereinafter referred to as “cycle time”) is measured and found to be approximately 24.7 seconds. Also, in the conventional bonding apparatus, with 63 chips taken as a sample, the time required for the process for obtaining the change amount in the offset distance is measured and found to be approximately 15.1 seconds. This time corresponds to 61% or more of the cycle time.

In contrast, in the bonding apparatus 100 and the bonding method of this embodiment, the reference mark 32 can be detected together with detection of the chip 72 to calculate the change amount Δod in the offset distance, so it is possible to reduce the time required for the process for obtaining the change amount in the offset distance in the conventional bonding apparatus, i.e., the time of approximately 15.1 seconds, to zero or substantially zero. Thus, the bonding apparatus 100 and the bonding method of this embodiment can shorten the cycle time to 39% or less compared to the conventional bonding apparatus.

In addition, the embodiment described above is intended to facilitate understanding of the present invention and is not intended to restrict interpretation of the present invention. The present invention may be modified/improved without departing from the spirit thereof, and the present invention also includes equivalents thereof. In other words, the embodiment and/or modification examples appropriately modified in design by those skilled in the art are also included in the scope of the present invention as long as they have the features of the present invention. For example, each element included in the embodiment and/or modification examples and their arrangement, material, condition, shape, size, etc. are not limited to those illustrated but may be changed as appropriate. Further, the embodiment and modification examples are illustrative, and obviously the configurations shown in different embodiments and/or modification examples may be partially replaced or combined, and such replacements and combinations are also included in the scope of the present invention as long as they include the features of the present invention.

### REFERENCE SIGNS LIST

12 . . . Wafer holding part
14 . . . Handling unit
15 . . . Stepping motor
16 . . . Rotating shaft
17 . . . Arm
18 . . . Base
19 . . . Pickup tool
20 . . . Bonding head part
21 . . . Z-axis drive mechanism
22 . . . Bonding tool
24 . . . Top camera
26 . . . XY table
28 . . . Bottom camera
30 . . . Reference member
31 . . . Support member
32 . . . Reference mark
40 . . . Bonding stage part
60 . . . Bonding control part
61 . . . Calculation part
62 . . . Movement control part
70 . . . Wafer
72 . . . Chip
80 . . . Substrate
100 . . . Bonding apparatus
CA1 . . . Central axis
CA2 . . . Central axis
g1 . . . First image
g2 . . . Second image
OA1 . . . Optical axis
OA2 . . . Optical axis
ODd . . . Offset distance
ODr . . . Offset distance
PD . . . Predetermined distance
S100 . . . Bonding process
Δbh . . . Deviation amount
Δmk . . . Deviation amount
Δod . . . Change amount

1. A bonding apparatus comprising:
a bonding head part which is movable and holds a first camera installed with an optical system oriented toward one side and a bonding tool arranged apart from the first camera by an offset distance;
a second camera installed with an optical system oriented toward another side to be capable of photographing the bonding head part;
a reference member which has a reference mark on a surface on the another side and is fixed at a position spaced apart from the second camera by a predetermined distance; and
a calculation part which calculates a change amount in the offset distance based on the predetermined distance, a position of the reference mark detected by the first camera, and a position of a chip detected by the second camera, when the bonding head part moves such that the reference mark is positioned within a field of view of the first camera and the chip held by the bonding tool is positioned within a field of view of the second camera, wherein the calculation part detects the position of the reference mark based on a first image captured by the first camera, and detects the position of the chip based on a second image captured by the second camera.

2. (canceled)

3. The bonding apparatus according to claim 1, wherein
the calculation part measures a deviation amount of the reference mark with respect to the first camera based on the first image, and measures a deviation amount of the chip with respect to the second camera based on the second image.

4. The bonding apparatus according to claim 1, further comprising:
a movement control part which controls movement of the bonding head part and determines a movement amount of the bonding head part based on the calculated change amount in the offset distance.

5. The bonding apparatus according tom claim 1, wherein
the second camera and the reference member are integrated.

6. The bonding apparatus according to claim 1, wherein
the predetermined distance is set based on the offset distance.

7. A bonding method, which is a bonding method of a bonding apparatus comprising:
a bonding head part which is movable and holds a first camera installed with an optical system oriented toward one side and a bonding tool arranged apart from the first camera by an offset distance;
a second camera installed with an optical system oriented toward another side to be capable of photographing the bonding head part; and
a reference member which has a reference mark on a surface on the another side and is fixed at a position spaced apart from the second camera by a predetermined distance,
the bonding method comprising:
detecting, by the first camera, a position of the reference mark, and detecting, by the second camera, a position of a chip held by the bonding tool; and
calculating a change amount in the offset distance based on the predetermined distance, the detected position of the reference mark, and the detected position of the chip, wherein
the calculating comprises detecting the position of the reference mark based on a first image captured by the first camera, and detecting the position of the chip based on a second image captured by the second camera.
